(19) United States
(12) Patent Application Publication
(10) Pub. No.: US 2024/0128015 A1
(43) Pub. Date: Apr. 18, 2024

(54) INDUCTOR COMPONENT

(71) Applicant: Murata Manufacturing Co., Ltd., Kyoto-fu (JP)

(72) Inventor: Keisuke KUNIMORI, Nagaokakyo-shi (JP)

(73) Assignee: Murata Manufacturing Co., Ltd., Kyoto-fu (JP)

(21) Appl. No.: 18/480,915

(22) Filed: Oct. 4, 2023

(30) Foreign Application Priority Data
Oct. 14, 2022 (JP) 2022-165741

(51) Int. Cl. H01F 27/32; H01F 27/29

(52) U.S. Cl. CPC H01F 27/323; H01F 27/292

(57) ABSTRACT

An inductor component includes a base body, first and second inner wiring line inside the base body, an inter-layer insulation layer, and a via-wiring line. The inter-layer insulation layer is inside the base body, and between the first and second inner wiring lines. The inter-layer insulation layer includes first and second major faces and a via-hole. The first major face faces the first inner wiring line. The second major face faces the second inner wiring line. The via-hole extends through the inter-layer insulation layer between the first and second major faces. The via-wiring line is in the via-hole, and electrically connects the first and second inner wiring lines. As seen in a first cross-section including a center axis of the via-wiring line, the via-wiring line includes a first portion in contact with the first inner wiring line, and a second portion in contact with the second inner wiring line.

### CROSS-REFERENCE TO RELATED APPLICATION

This application claims benefit of priority to Japanese Patent Application No. 2022-165741, filed Oct. 14, 2022, the entire content of which is incorporated herein by reference.

### BACKGROUND

### Technical Field

The present disclosure relates to an inductor component.

### Background Art

An exemplary electronic component according to the related art is described in Japanese Unexamined Patent Application Publication No. 2020-107877. The electronic component includes two inner wiring lines, an insulation layer, and a via-wiring line. The insulation layer is disposed between the two inner wiring lines, and has a via-hole. The via-wiring line is passed through the via-hole. The via-wiring line electrically connects the two inner wiring lines to each other. The via-hole tapers to decrease in diameter in the direction of depth.

### SUMMARY

Potential issues with such an electronic component according to the related art include disconnection of the via-wiring line from the insulation layer, and reduced reliability of connection between the via-wiring line and each inner wiring line due to insufficient strength of connection between the via-wiring line and the inner wiring line.

Accordingly, the present disclosure provides an inductor component that can have improved strength of connection between a via-wiring line and each inner wiring line.

To address the above-mentioned issues, an inductor component according to an aspect of the present disclosure includes a base body, a first inner wiring line, a second inner wiring line, an inter-layer insulation layer, and a via-wiring line. The first inner wiring line and the second inner wiring line are disposed inside the base body. The inter-layer insulation layer is disposed inside the base body and located between the first inner wiring line and the second inner wiring line. The inter-layer insulation layer includes a first major face, a second major face, and a via-hole. The first major face faces the first inner wiring line. The second major face faces the second inner wiring line. The via-hole extends through the inter-layer insulation layer between the first major face and the second major face. The via-wiring line is inserted in the via-hole, and electrically connects the first inner wiring line and the second inner wiring line to each other. As seen in a first cross-section including a center axis of the via-wiring line, the via-wiring line includes a first portion in contact with the first inner wiring line, and a second portion in contact with the second inner wiring line. The first portion has a width that decreases in a direction from the first inner wiring line toward the second inner wiring line. The second portion has a width that increases in the direction from the first inner wiring line toward the second inner wiring line.

As used herein, the term “center axis” refers to a line passing through the center of gravity of the via-wiring line and perpendicular to the first major face. The term “width” refers to a size in a direction orthogonal to the center axis. Preferably, the “first cross-section” is a cross-section in which the via-wiring line has the maximum width. When it is stated herein that the first portion or the second portion is “in contact”, this means that part (e.g., an end face) of the first portion or the second portion is in contact.

According to the above-mentioned aspect, the first portion has a width that decreases in the direction from the first inner wiring line toward the second inner wiring line, and the second portion has a width that increases in the direction from the first inner wiring line toward the second inner wiring line. This allows the inter-layer insulation layer to wedge into the via-wiring line, leading to reduced risk of disconnection of the via-wiring line from the inter-layer insulation layer. The configuration mentioned above makes it possible to improve the strength of connection between the via-wiring line and each of the first inner wiring line and the second inner wiring line.

The first portion has a comparatively large width near the first inner wiring line. This allows for increased area of contact between the first portion and the first inner wiring line. The second portion has a comparatively large width near the second inner wiring line. This allows for increased area of contact between the second portion and the second inner wiring line. The configuration mentioned above makes it possible to improve the strength of connection between the via-wiring line and each of the first inner wiring line and the second inner wiring line.

An inductor component according to an aspect of the present disclosure includes a base body, a first inner wiring line, a second inner wiring line, an inter-layer insulation layer, and a via-wiring line. The first inner wiring line and the second inner wiring line are disposed inside the base body. The inter-layer insulation layer is disposed inside the base body and located between the first inner wiring line and the second inner wiring line. The inter-layer insulation layer includes a first major face, a second major face, and a via-hole. The first major face faces the first inner wiring line. The second major face faces the second inner wiring line. The via-hole extends through the inter-layer insulation layer between the first major face and the second major face. The via-wiring line is inserted in the via-hole, and electrically connects the first inner wiring line and the second inner wiring line to each other. As seen in a first cross-section including a center axis of the via-wiring line, the via-wiring line includes a first portion in contact with the first inner wiring line, and a second portion in contact with the second inner wiring line. The first portion has a width that increases in a direction from the first inner wiring line toward the second inner wiring line. The second portion has a width that decreases in the direction from the first inner wiring line toward the second inner wiring line.

According to the above-mentioned aspect, the first portion has a width that increases in the direction from the first inner wiring line toward the second inner wiring line, and the second portion has a width that decreases in the direction from the first inner wiring line toward the second inner wiring line. This allows the via-wiring line to wedge into the inter-layer insulation layer, leading to reduced risk of disconnection of the via-wiring line from the inter-layer insulation layer. The configuration mentioned above makes it possible to improve the strength of connection between the via-wiring line and each of the first inner wiring line and the second inner wiring line.

The inductor component according to an aspect of the present disclosure can have improved strength of connection between the via-wiring line and each inner wiring line.

### BRIEF DESCRIPTION OF THE DRAWINGS

FIG. 1 is a see-through plan view of an inductor component according to a first embodiment;

FIG. 2 illustrates a cross-section taken along II-II in FIG. 1;

FIG. 3 is an enlarged view of a portion A in FIG. 2;

FIG. 4 is an enlarged view of a portion A in FIG. 3;

FIG. 5A is a schematic cross-sectional illustration for explaining a method for producing an inductor component;

FIG. 5B is a schematic cross-sectional illustration for explaining a method for producing an inductor component;

FIG. 5C is a schematic cross-sectional illustration for explaining a method for producing an inductor component;

FIG. 5D is a schematic cross-sectional illustration for explaining a method for producing an inductor component;

FIG. 5E is a schematic cross-sectional illustration for explaining a method for producing an inductor component;

FIG. 5F is a schematic cross-sectional illustration for explaining a method for producing an inductor component;

FIG. 5G is a schematic cross-sectional illustration for explaining a method for producing an inductor component;

FIG. 5H is a schematic cross-sectional illustration for explaining a method for producing an inductor component;

FIG. 5I is a schematic cross-sectional illustration for explaining a method for producing an inductor component;

FIG. 5J is a schematic cross-sectional illustration for explaining a method for producing an inductor component;

FIG. 5K is a schematic cross-sectional illustration for explaining a method for producing an inductor component;

FIG. 5L is a schematic cross-sectional illustration for explaining a method for producing an inductor component;

FIG. 5M is a schematic cross-sectional illustration for explaining a method for producing an inductor component;

FIG. 6 is a schematic cross-sectional view of an inductor component according to a second embodiment; and

FIG. 7 is a schematic cross-sectional view of an inductor component according to a third embodiment.

### DETAILED DESCRIPTION

An inductor component according to an aspect of the present disclosure is described below in more detail by way of its embodiments illustrated in the drawings. The drawings are partly schematic in nature, and do not reflect the actual dimensions or proportions in some cases.

### First Embodiment

### Configuration

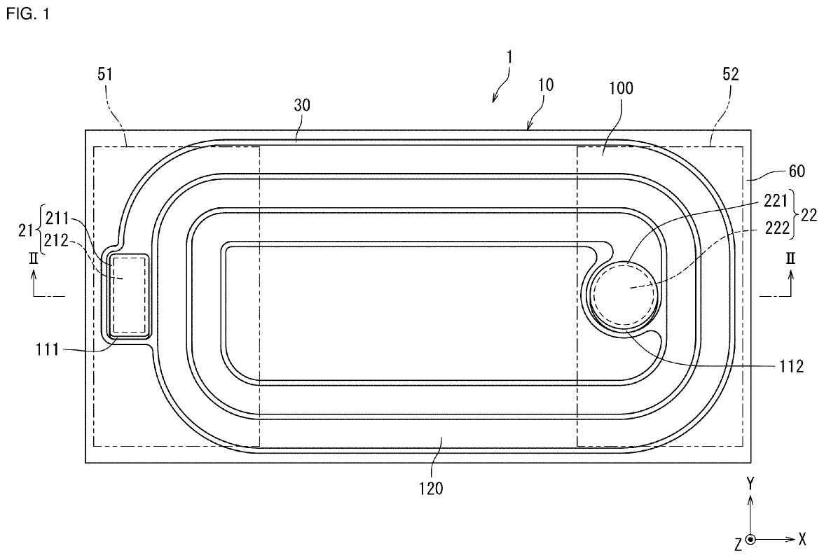

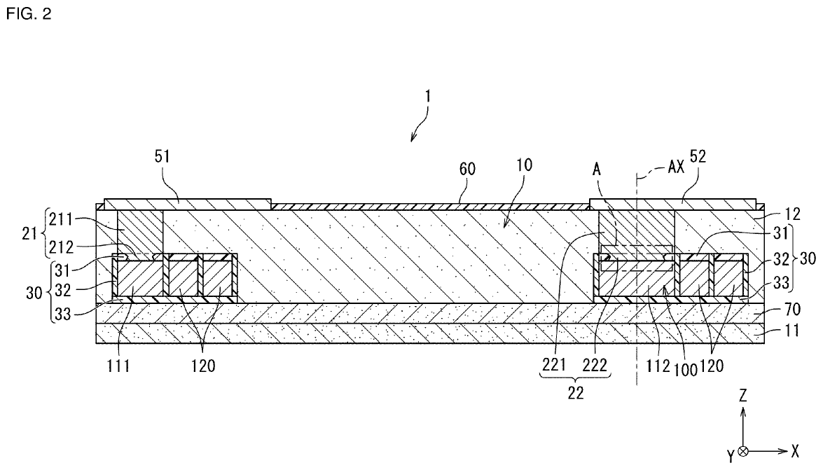

FIG. 1 is a see-through plan view of an inductor component according to an embodiment. FIG. 2 illustrates a cross-section taken along II-II in FIG. 1. FIG. 2 illustrates an XZ cross-section including a center axis AX of via-wiring lines. The XZ cross-section is an example of a first cross-section including the center axis AX. In FIG. 2, a seed layer is not depicted for convenience.

In the drawings, the direction of thickness of an inductor component 1 is defined as a Z-direction. In a plane orthogonal to the Z-direction of the inductor component 1, a direction that is the lengthwise direction of the inductor component 1 and in which a first outer terminal 51 and a second outer terminal 52 are arranged side by side is defined as an X-direction. The widthwise direction of the inductor component 1, which is orthogonal to the lengthwise direction, is defined as a Y-direction. The XZ cross-section is a cross-section of the inductor component 1 taken along a plane that is defined by a straight line extending in the X-direction and a straight line extending in the Z-direction, and that includes the center axis AX of each via-wiring line.

The inductor component 1 is incorporated in, for example, electronics such as personal computers, DVD players, digital cameras, TVs, mobile phones, and automotive electronics. The inductor component 1 has, for example, a generally cuboid shape. It is to be noted, however, that the shape of the inductor component 1 is not particularly limited but may be a circular cylinder, a polygonal prism, a circular truncated cone, or a polygonal frustum.

As illustrated in FIGS. 1 and 2, the inductor component 1 includes a base body 10, an inductor wiring line 100, an insulation layer 30, a first vertical wiring line 21, a second vertical wiring line 22, the first outer terminal 51, the second outer terminal 52, and a covering film 60. In FIG. 1, the outer terminals are represented by chain double-dashed lines for convenience. Although the base body 10, the covering film 60, and an inter-layer insulation layer 31 of the insulation layer 30 are depicted in FIG. 1 as being transparent for the ease of understanding of the general structure, these components may be translucent or opaque.

The base body 10 includes a first magnetic layer 11, a substrate 70, and a second magnetic layer 12. The substrate 70 is disposed on the first magnetic layer 11. The second magnetic layer 12 is disposed on the substrate 70. The substrate 70 and the second magnetic layer 12 are stacked with the inductor wiring line 100 and the insulation layer 30 sandwiched therebetween. That is, the inductor wiring line 100 and the insulation layer 30 are disposed inside the base body 10. Although the base body 10 is of a three-layer structure including the first magnetic layer 11, the substrate 70, and the second magnetic layer 12, the base body 10 may be of a two-layer structure including the first magnetic layer 11 and the second magnetic layer 12.

A direction such as upper or upward refers to a direction that, with respect to a direction orthogonal to a major face (upper face) of the substrate 70 facing the second magnetic layer 12 (or the Z-direction), points from the first magnetic layer 11 toward the second magnetic layer 12. An upper face of an element refers to an upwardly located face of the element. A direction such as lower or downward refers to a direction that, with respect to the direction orthogonal to the major face of the substrate 70 facing the second magnetic layer 12, points from the second magnetic layer 12 toward the first magnetic layer 11. A lower face of an element refers to a downwardly located face of the element. The direction of the center axis AX of a second via-wiring line 222 coincides with the direction orthogonal to the major face of the substrate 70 facing the second magnetic layer 12.

As used herein, the term “inductor wiring line” means a curved line (two-dimensional curve) extending in a plane. An inductor wiring line may be a curved line with a number of turns greater than one, or may be a curved line with a number of turns less than one. An inductor wiring line may partially include a straight-line portion.

The first magnetic layer 11 and the second magnetic layer 12 each include a resin, and a metal magnetic powder serving as a magnetic substance contained in the resin. Consequently, as compared with a case where such magnetic layers are made of ferrite, the presence of the metal magnetic powder allows for improved direct-current superposition characteristics, and the resin provides insulation between metal magnetic powder particles. This helps to reduce loss (iron loss) at high frequencies.

An example of the resin is an epoxy resin, a polyimide resin, a phenolic resin, or a vinyl ether resin. This allows for improved reliability of insulation. More specifically, the resin is an epoxy resin, a mixture of epoxy and acrylic resins, or a mixture of epoxy, acrylic, and other resins. This ensures insulation between metal magnetic powder particles, and consequently allows for reduced loss (iron loss) at high frequencies.

The metal magnetic powder has a mean particle diameter of, for example, greater than or equal to 0.1 μm and less than or equal to 5 μm (i.e., from 0.1 μm to 5 μm). In the production stage for the inductor component 1, the mean particle diameter of the metal magnetic powder can be calculated as a particle diameter corresponding to the 50th percentile of the cumulative particle size distribution determined by the laser diffraction/scattering method. An example of the metal magnetic powder is an FeSi-based alloy such as FeSiCr, an FeCo-based alloy, an Fe-based alloy such as NiFe, or an amorphous alloy thereof. The metal magnetic powder is contained at a proportion of preferably greater than or equal to 20 vol % and less than or equal to 70 vol % (i.e., from 20 vol % to 70 vol %) of the whole magnetic layer. Use of a metal magnetic powder with a mean particle diameter of less than or equal to 5 μm allows for further improved direct-current superposition characteristics, and reduced iron loss at high frequencies due to the fine powder particle size. Use of a metal magnetic powder with a mean particle diameter of greater than or equal to 0. 1 μm facilitates uniform dispersion in the resin, leading to improved production efficiency for the first magnetic layer 11 and the second magnetic layer 12. Instead of or in addition to the metal magnetic powder, an NiZn- or MnZn-based ferrite magnetic powder may be used.

The substrate 70 is stacked on the first magnetic layer 11. The substrate 70 is in the form of a flat plate, and serves as a base for the production process of the inductor component 1. The substrate 70 is, for example, a sintered body such as a magnetic substrate made of a NiZn ferrite, a MnZn ferrite, or other type of ferrite, or a non-magnetic substrate made of alumina or glass. The substrate 70 has a thickness of, for example, greater than or equal to 300 μm and less than or equal to 1000 μm (i.e., from 300 μm to 1000 μm).

The inductor wiring line 100 is disposed over the upper face of the substrate 70, and extends in parallel to the upper face of the substrate 70. The inductor wiring line 100 is wound in a spiral around the axis of the inductor wiring line 100 over the upper face of the substrate 70. The inductor wiring line 100 has the shape of a spiral with more than one turn. As seen from above, the inductor wiring line 100 is wound clockwise in a spiral pattern from the outer circumferential end toward the inner circumferential end. The inductor wiring line 100 may be a curved line with less than one turn, or may partially include a straight-line portion.

The inductor wiring line 100 has a thickness of, for example, greater than or equal to 40 μm and less than or equal to 120 μm (i.e., from 40 μm to 120 μm). Specifically, the inductor wiring line 100 has a thickness of 45 μm, a line width of 50 μm, and a line-to-line spacing of 10 μm. The line-to-line spacing may be greater than or equal to 3 μm and less than or equal to 20 μm (i.e., from 3 μm to 20 μm).

The inductor wiring line 100 includes a spiral portion 120, a first pad portion 111, and a second pad portion 112. The first pad portion 111 is connected to the first vertical wiring line 21. The second pad portion 112 is connected to the second vertical wiring line 22. The spiral portion 120 extends from the first pad portion 111 and the second pad portion 112 in a spiral pattern in parallel to the upper face of the substrate 70, with the first pad portion 111 serving as the outer circumferential end and the second pad portion 112 serving as the inner circumferential end.

The first vertical wiring line 21 and the second vertical wiring line 22 extend in the direction of the center axis AX from the inductor wiring line 100, and penetrate the base body 10. The first vertical wiring line 21 includes a first via-wiring line 212, and a first columnar wiring line 211. The first via-wiring line 212 extends upward from the upper face of the first pad portion 111 of the inductor wiring line 100, and penetrates an inner portion of the inter-layer insulation layer 31. The first columnar wiring line 211 extends upward from the first via-wiring line 212, and penetrates an inner portion of the second magnetic layer 12. The second vertical wiring line 22 includes the second via-wiring line 222, and a second columnar wiring line 221. The second via-wiring line 222 extends upward from the upper face of the second pad portion 112 of the inductor wiring line 100, and penetrates the inter-layer insulation layer 31. The second columnar wiring line 221 extends upward from the second via-wiring line 222, and penetrates an inner portion of the second magnetic layer 12.

The inductor wiring line 100 corresponds to an example of “first inner wiring line” recited in the claims. The first columnar wiring line 211 and the second columnar wiring line 221 correspond to an example of “second inner wiring line” recited in the claims. The inductor wiring line 100 is made of an electrically conductive material. For example, the inductor wiring line 100 is made of a metallic material with low electrical resistance, such as Cu, Ag, Au, Fe, or an alloy containing these metals. This allows for reduced direct-current resistance of the inductor component 1. The first vertical wiring line 21 and the second vertical wiring line 22 are made of a conductive material similar to that of the inductor wiring line 100.

The insulation layer 30 covers at least part of the inductor wiring line 100. The insulation layer 30 includes the inter-layer insulation layer 31, resin walls 32, and an underlying insulation layer 33. The inter-layer insulation layer 31 covers the upper face of the inductor wiring line 100. The resin walls 32 cover the lateral faces of the inductor wiring line 100. The underlying insulation layer 33 covers the lower face of the inductor wiring line 100. Specifically, the resin walls 32 are located in the same plane as the inductor wiring line 100, and disposed at locations such as between turns of the inductor wiring line 100 and near the radially outer and inner portions of the inductor wiring line 100. The inter-layer insulation layer 31 covers the upper face of the inductor wiring line 100, and has a via-hole at a location corresponding to each of the first and second pad portions 111 and 112 of the inductor wiring line 100. The inter-layer insulation layer 31 is disposed so as to fill in the space between the respective upper ends of adjacent resin walls 32.

Each of the inter-layer insulation layer 31, the resin walls 32, and the underlying insulation layer 33 is made of an insulative material containing no magnetic substance, and includes, for example, one of the following resins: an epoxy resin, a polyimide resin, a phenolic resin, and a vinyl ether resin. This allows for improved reliability of insulation. The underlying insulation layer 33 may include a non-magnetic filler such as silica. The underlying insulation layer 33 has a thickness of, for example, less than or equal to 10 μm.

The first outer terminal 51 is disposed on the upper face of the second magnetic layer 12, and covers an end face of the first columnar wiring line 211 that is exposed from the upper face of the second magnetic layer 12. The first outer terminal 51 is thus electrically connected to the first pad portion 111 of the inductor wiring line 100. The second outer terminal 52 is disposed on the upper face of the second magnetic layer 12, and covers an end face of the second columnar wiring line 221 that is exposed from the upper face of the second magnetic layer 12. The second outer terminal 52 is thus electrically connected to the second pad portion 112 of the inductor wiring line 100.

The first outer terminal 51 and the second outer terminal 52 are made of an electrically conductive material. Each of the first outer terminal 51 and the second outer terminal 52 is of, for example, a three-layer structure with the following metallic layers stacked in the order stated below from an inner side portion toward an outer side portion: a metallic layer made of Cu with low electrical resistance and superior stress resistance; a metallic layer made of Ni with superior corrosion resistance; and a metallic layer made of Au with superior wettability and reliability.

The covering film 60 is made of an insulative material. The covering film 60 covers the upper face of the second magnetic layer 12 in such a way that the respective end faces of the columnar wiring lines 211 and 221 and the respective end faces of the outer terminals 51 and 52 are exposed. The presence of the covering film 60 ensures insulation of the surface of the inductor component 1. The covering film 60 may be disposed at the lower face of the first magnetic layer 11.

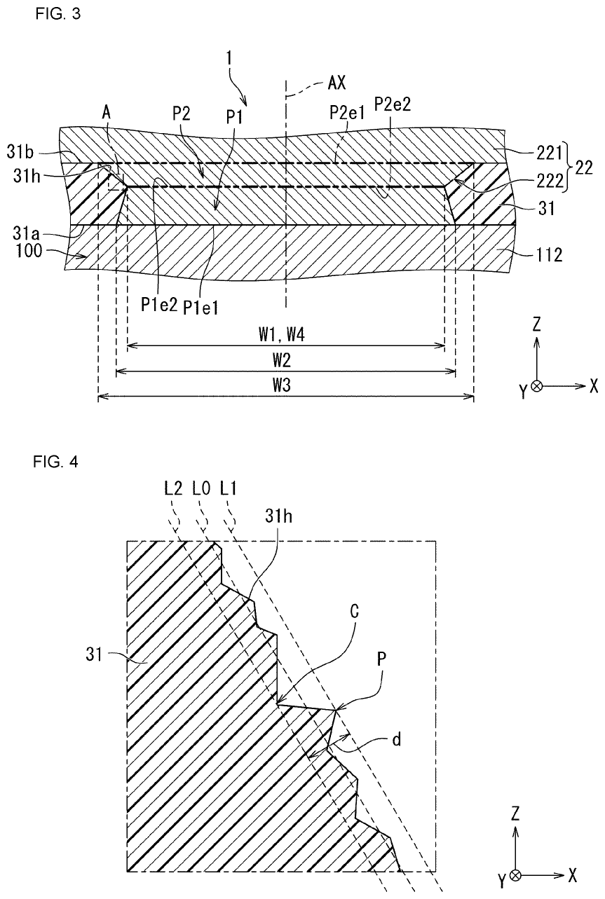

FIG. 3 is an enlarged view of a portion A illustrated in FIG. 2. FIG. 3 illustrates a portion of a first cross-section including the center axis AX of the second via-wiring line 222.

As illustrated in FIG. 3, the inter-layer insulation layer 31 is disposed between the inductor wiring line 100 (first inner wiring line) and the second columnar wiring line 221 (second inner wiring line). The inter-layer insulation layer 31 includes a first major face 31a, a second major face 31b, and a via-hole 31h. The first major face 31a faces the inductor wiring line 100. The second major face 31b faces the second columnar wiring line 221. The via-hole 31h extends through the inter-layer insulation layer 31 between the first major face 31a and the second major face 31b. The second via-wiring line 222 is inserted in the via-hole 31h, and electrically connects the inductor wiring line 100 and the second columnar wiring line 221 to each other.

The second via-wiring line 222 includes a first portion P1, and a second portion P2. The first portion P1 is in contact with the inductor wiring line 100. The second portion P2 is in contact with the second columnar wiring line 221. The first portion P1 has a width that decreases in the direction from the inductor wiring line 100 toward the second columnar wiring line 221. The second portion P2 has a width that increases in the direction from the inductor wiring line 100 toward the second columnar wiring line 221.

As seen in the cross-section illustrated in FIG. 3, a width of the first portion P1 refers to a size of the first portion P1 in a direction (X-direction) orthogonal to the center axis AX. Likewise, as seen in the cross-section illustrated in FIG. 3, a width of the second portion P2 refers to a size of the second portion P2 in the direction (X-direction) orthogonal to the center axis AX.

In FIG. 3, the boundary between the first portion P1 and the second portion P2, and the boundary between the second portion P2 and the second columnar wiring line 221 are represented by chain double-dashed lines for convenience. If the upper face of the second portion P2 has a width equal to the width of the lower face of the second columnar wiring line 221, the boundary between the second portion P2 and the second columnar wiring line 221 may be a plane including the second major face 31b of the inter-layer insulation layer 31.

Specifically, the first portion P1 has a width that decreases progressively in the direction from the inductor wiring line 100 toward the second columnar wiring line 221. More specifically, as seen in the cross-section illustrated in FIG. 3, each lateral face of the first portion P1 is inclined such that its distance to the center axis AX decreases in the direction from the inductor wiring line 100 toward the second columnar wiring line 221. In short, as seen in the cross-section illustrated in FIG. 3, the first portion P1 has the shape of a trapezoid.

The second portion P2 has a width that increases progressively in the direction from the inductor wiring line 100 toward the second columnar wiring line 221. More specifically, as seen in the cross-section illustrated in FIG. 3, each lateral face of the second portion P2 is inclined such that its distance to the center axis AX increases in the direction from the inductor wiring line 100 toward the second columnar wiring line 221. In short, as seen in the cross-section illustrated in FIG. 3, the second portion P2 has the shape of an inverted trapezoid.

According to the first embodiment, the first portion P1 and the second portion P2 are in contact with each other. In other words, the first portion P1 and the second portion P2 are contiguous to each other in the Z-direction. The first portion P1 and the second portion P2 are integral with each other. The second via-wiring line 222 thus has a constricted shape.

The shape of the first portion P1 is not particularly limited as long as the first portion P1 has a width that decreases in the direction from the inductor wiring line 100 toward the second columnar wiring line 221. In one example, as seen in the cross-section illustrated in FIG. 3, one lateral face of the first portion P1 may be parallel to the Z-direction. In another example, the first portion P1 may have a width that decreases in a stepwise fashion in the direction from the inductor wiring line 100 toward the second columnar wiring line 221.

Likewise, the shape of the second portion P2 is not particularly limited as long as the second portion P2 has a width that increases in the direction from the inductor wiring line 100 toward the second columnar wiring line 221. In one example, as seen in the cross-section illustrated in FIG. 3, one lateral face of the second portion P2 may be parallel to the Z-direction. In another example, the second portion P2 may have a width that increases in a stepwise fashion in the direction from the inductor wiring line 100 toward the second columnar wiring line 221.

According to the first embodiment, as illustrated in FIG. 2, the first via-wiring line 212 is similar in configuration to the second via-wiring line 222. That is, the first via-wiring line 212 includes a first portion in contact with the inductor wiring line 100, and a second portion in contact with the first columnar wiring line 211. The first portion has a width that decreases in the direction from the inductor wiring line 100 toward the first columnar wiring line 211, and the second portion has a width that increases in the direction from the inductor wiring line 100 toward the first columnar wiring line 211. The first via-wiring line 212 thus has a constricted shape.

In the inductor component 1, as mentioned above, the first portion P1 of the second via-wiring line 222 has a width that decreases in the direction from the inductor wiring line 100 toward the second columnar wiring line 221. This configuration helps to reduce potential disconnection of the second via-wiring line 222 from the inter-layer insulation layer 31 in the direction from the inductor wiring line 100 toward the second columnar wiring line 221. This allows for improved strength of connection between the first portion P1 and the inductor wiring line 100. Further, as mentioned above, the second portion P2 of the second via-wiring line 222 has a width that increases in the direction from the inductor wiring line 100 toward the second columnar wiring line 221. This configuration helps to reduce potential disconnection of the second via-wiring line 222 from the inter-layer insulation layer 31 in the direction from the second columnar wiring line 221 toward the inductor wiring line 100. This allows for improved strength of connection between the second portion P2 and the second columnar wiring line 221. The configuration mentioned above therefore makes it possible to improve the strength of connection between the second via-wiring line 222, and each of the inductor wiring line 100 and the second columnar wiring line 221.

In other words, since the first portion P1 has a width that decreases in the direction from the inductor wiring line 100 toward the second columnar wiring line 221, and the second portion P2 has a width that increases in the direction from the inductor wiring line 100 toward the second columnar wiring line 221, the inter-layer insulation layer 31 wedges into the second via-wiring line 222, leading to reduced risk of disconnection of the second via-wiring line 222 from the inter-layer insulation layer 31. The configuration mentioned above makes it possible to improve the strength of connection between the second via-wiring line 222, and each of the inductor wiring line 100 and the second columnar wiring line 221.

Due to the configuration mentioned above, the first portion P1 has a comparatively large width near the inductor wiring line 100. This allows for increased area of contact between the first portion P1 and the inductor wiring line 100. Likewise, the second portion P2 has a comparatively large width near the second columnar wiring line 221. This allows for increased area of contact between the second portion P2 and the second columnar wiring line 221. The configuration mentioned above thus makes it possible to improve the strength of connection between the second via-wiring line 222, and each of the inductor wiring line 100 and the second columnar wiring line 221.

According to the configuration of the inductor component 1 mentioned above, the first via-wiring line 212 likewise includes a first portion with a width that decreases in the direction from the inductor wiring line 100 toward the first columnar wiring line 211, and a second portion with a width that increases in the direction from the inductor wiring line 100 toward the first columnar wiring line 211. The same operational effect as mentioned above with reference to the second via-wiring line 222 is thus obtained for the first via-wiring line 212 as well. That is, the configuration mentioned above makes it possible to improve the strength of connection between the first via-wiring line 212, and each of the inductor wiring line 100 and the second columnar wiring line 211.

Preferably, as seen in a second cross-section (YZ cross-section) including the center axis AX of the second via-wiring line 222 and orthogonal to the first cross-section (XZ cross-section), the first portion P1 has a width that decreases in the direction from the inductor wiring line 100 toward the second columnar wiring line 221, and the second portion P2 has a width that increases in the direction from the inductor wiring line 100 toward the second columnar wiring line 221. This makes it possible to further improve the strength of connection between the second via-wiring line 222, and each of the inductor wiring line 100 and the second columnar wiring line 221. Preferably, the first via-wiring line 212 has a configuration similar to the configuration mentioned above.

Preferably, as illustrated in FIG. 3, the first portion P1 and the second portion P2 are in contact with each other. The first portion P1 includes a first end face P1e1, and a second end face P1e2. The first end face P1e1 is in contact with the inductor wiring line 100. The second end face P1e2 is in contact with the second portion P2. The second portion P2 includes a first end face P2e1, and a second end face P2e2. The first end face P2e1 is in contact with the second columnar wiring line 221. The second end face P2e2 is in contact with the first portion P1. As seen in the first cross-section, a width W1 of the second end face P1e2 of the first portion P1 is equal to a width W4 of the second end face P2e2 of the second portion P2. A width W2 of the first end face P1e1 of the first portion P1, and a width W3 of the first end face P2e1 of the second portion P2 are greater than the width W1 of the second end face Ple2 of the first portion P1 and the width W4 of the second end face P2e2 of the second portion P2.

The first cross-section refers to a cross-section in which the second via-wiring line 222 has the maximum width (i.e., the cross-section illustrated in FIG. 3). The configuration mentioned above makes it possible to increase the area of contact between the first end face P1e1 of the first portion P1 and the inductor wiring line 100, and consequently improve the strength of connection between the second via-wiring line 222 and the inductor wiring line 100. The configuration mentioned above likewise makes it possible to increase the area of contact between the first end face P2e1 of the second portion P2 and the second columnar wiring line 221, and consequently improve the strength of connection between the second via-wiring line 222 and the second columnar wiring line 221.

The first via-wiring line 212 may have a configuration similar to the configuration mentioned above. That is, as for the first via-wiring line 212 as well, as seen in a first cross-section, the width of the second end face of the first portion may be equal to the width of the second end face of the second portion, and the width of the first end face of the first portion and the width of the first end face of the second portion may be greater than the width of the second end face of the first portion and the width of the second end face of the second portion. The first cross-section in this case refers to a cross-section in which the first via-wiring line 212 has the maximum width. Specifically, as seen in the Z-direction, the first cross-section refers to a cross-section passing through the opposite corners of the first via-wiring line 212. The configuration mentioned above provides an operational effect similar to that mentioned above with reference to the second via-wiring line 222.

Preferably, as seen in the first cross-section (i.e., the cross-section illustrated in FIG. 3), the width W1 of the second end face P1e2 of the first portion P1 of the second via-wiring line 222 is greater than 0.8 times the width W2 of the first end face P1e1 of the first portion P1.

According to the configuration mentioned above, the width W1 of the second end face P1e2 of the first portion P1 is greater than 0.8 times the width W2 of the first end face P1e1 of the first portion P1. This makes it possible to ensure sufficient cross-sectional area near the second end face P1e2 of the first portion P1, ensure sufficient strength of the second via-wiring line 222, and reduce the electrical resistance of the second via-wiring line 222. The first via-wiring line 212 may have a configuration similar to the configuration mentioned above.

Preferably, as illustrated in FIG. 2, the inductor component 1 includes the second outer terminal 52 that is disposed on the base body 10 at a location closer to the second columnar wiring line 221 than to the inductor wiring line 100, and that is electrically connected to the second columnar wiring line 221. As illustrated in FIG. 3, the first portion P1 of the second via-wiring line 222 includes the first end face P1e1 in contact with the inductor wiring line 100, and the second portion P2 includes the first end face P2e1 in contact with the second columnar wiring line 221. As seen in the first cross-section, the width W3 of the first end face P2e1 of the second portion P2 is greater than the width W2 of the first end face P1el of the first portion P1.

The first cross-section in this case refers to a cross-section in which the second via-wiring line 222 has the maximum width (i.e., the cross-section illustrated in FIG. 3). According to the configuration mentioned above, the second outer terminal 52 is disposed on the base body 10 at a location closer to the second columnar wiring line 221 than to the inductor wiring line 100. Accordingly, in mounting the inductor component 1, more stress tends to act at a location near the second columnar wiring line 221 than at a location near the inductor wiring line 100. At this time, since the width W3 of the first end face P2e1 of the second portion P2 of the second via-wiring line 222 is greater than the width W2 of the first end face P1e1 of the first portion P1, the area of contact of the first end face P2e1 of the second portion P2 with the second columnar wiring line 221 is greater than the area of contact of the first end face P1e1 of the first portion P1 with the inductor wiring line 100. This makes it possible to effectively reduce potential separation between the second via-wiring line 222 and the second columnar wiring line 221 caused by stress exerted in mounting the inductor component 1.

Preferably, as illustrated in FIG. 2, the inductor component 1 likewise includes the first outer terminal 51 that is disposed on the base body 10 at a location closer to the first columnar wiring line 211 than to the inductor wiring line 100, and that is electrically connected to the first columnar wiring line 211. The first portion of the first via-wiring line 212 includes a first end face in contact with the inductor wiring line 100, and the second portion includes a first end face in contact with the first columnar wiring line 211. As seen in a first cross-section, the first end face of the second portion has a width greater than the width of the first end face of the first portion.

The first cross-section in this case refers to a cross-section in which the first via-wiring line 212 has the maximum width. Specifically, as seen in the Z-direction, the first cross-section refers to a cross-section passing through the opposite corners of the first via-wiring line 212. According to the configuration mentioned above, the first outer terminal 51 is disposed on the base body 10 at a location closer to the first columnar wiring line 211 than to the inductor wiring line 100. Accordingly, in mounting the inductor component 1, more stress tends to act at a location near the first columnar wiring line 211 than at a location near the inductor wiring line 100. At this time, since the width of the first end face of the second portion of the first via-wiring line 212 is greater than the width of the first end face of the first portion, the area of contact of the first end face of the second portion with the first columnar wiring line 211 is greater than the area of contact of the first end face of the first portion with the inductor wiring line 100. This makes it possible to effectively reduce potential separation between the first via-wiring line 212 and the first columnar wiring line 211 caused by stress exerted in mounting the inductor component 1.

Preferably, the inner face of the via-hole 31h in the inter-layer insulation layer 31 has a mean surface roughness of less than or equal to 1 μm. A method for measuring the surface roughness is now described below. FIG. 4 is an enlarged view of a portion A illustrated in FIG. 3. Observing a portion of the inner face of the via-hole 31h with a scanning electron microscope (SEM) or other device at a magnification of about 2000 times (field of view: about 5 μm per side) gives a cross-sectional photograph as illustrated in FIG. 4. A via-wiring line has projections P and depressions C along a lateral face. A reference line LO to be drawn along the lateral face of the via-wiring line is calculated by a method such as the least-squares method based on the projections P and the depressions C. The surface roughness is determined based on the depression C located at the greatest perpendicular distance from the reference line L0, and the projection P located at the greatest perpendicular distance from the reference line L0. A first straight line L1 parallel to the reference line L0 is drawn so as to pass through the top of the projection P, and a second straight line L2 parallel to the reference line L0 is drawn so as to pass through the bottom of the depression C located at the greatest perpendicular distance. The perpendicular distance d between the two straight lines L1 and L2 is measured. Then, the perpendicular distance d is measured at a total of four locations along the inner face of the via-hole 31h, including two locations corresponding to the first portion P1, and two locations corresponding to the second portion P2. The mean of the perpendicular distances d calculated at these locations is calculated to determine the surface roughness. The configuration mentioned above makes it possible to reduce resistance loss that is particularly significant at high frequencies due to the skin effect.

### Production Method

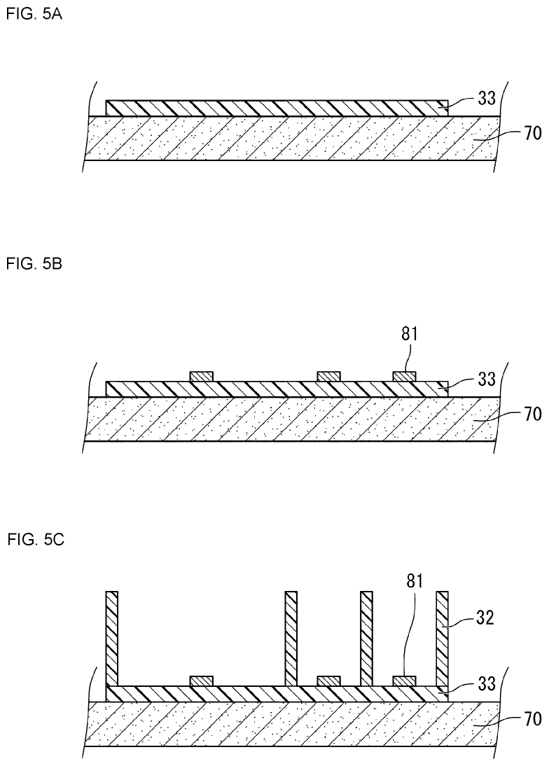

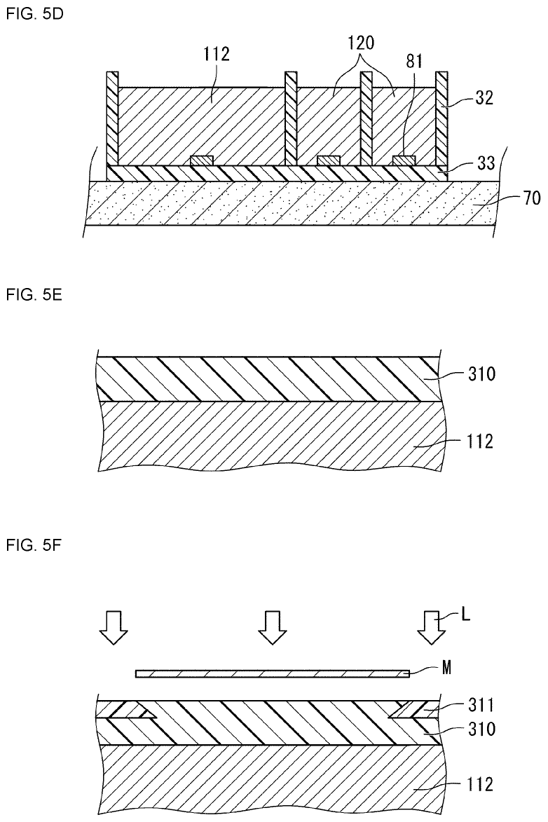

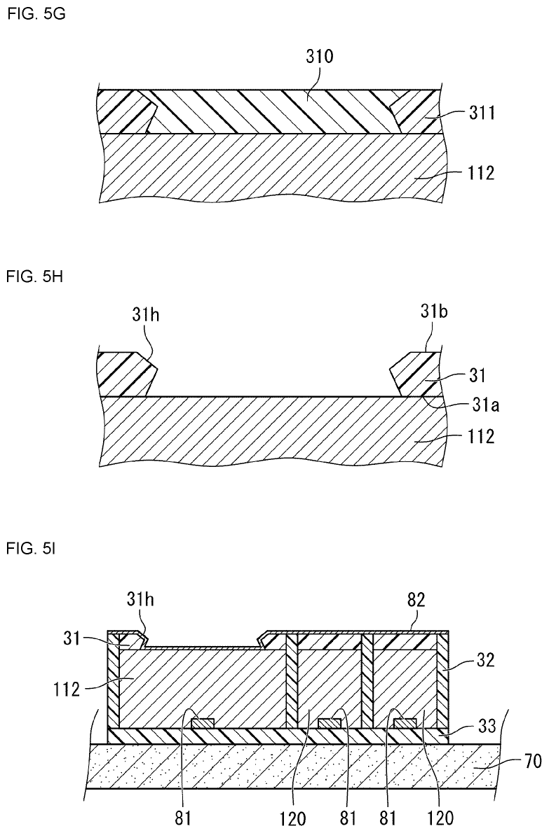

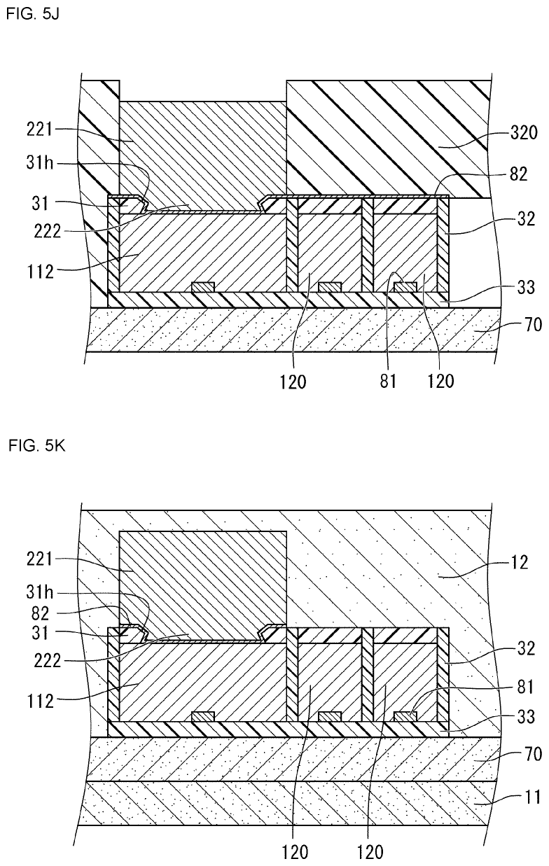

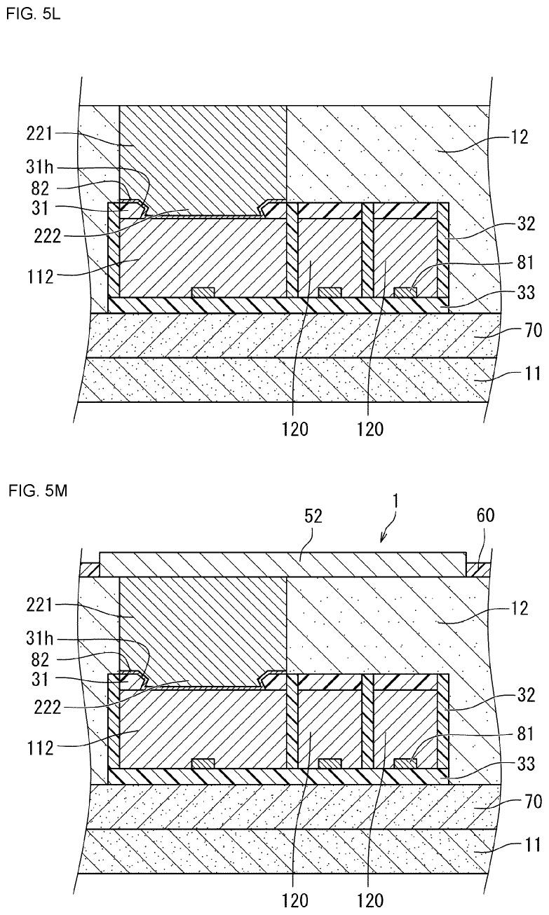

A method for producing the inductor component 1 is described below with reference to FIGS. 5A to 5M. FIGS. 5A to 5M are illustrations corresponding to the second pad portion 112 of the inductor wiring line 100 illustrated in FIG. 2 and the second vertical wiring line 22 illustrated in FIG. 2. The same description given below similarly applies to the first pad portion 111 and the first vertical wiring line 21. The first pad portion 111 and the first vertical wiring line 21 are thus not described below in further detail.

As illustrated in FIG. 5A, the underlying insulation layer 33 containing no magnetic substance is formed on the substrate 70. For example, the substrate 70 is made of sintered ferrite, and in the form of a flat plate.

The underlying insulation layer 33 is made of, for example, a polyimide resin or inorganic material containing no magnetic substrate. The substrate 70 is coated with a polyimide resin by a method such as printing or application, and then subjected to patterning using photolithography such that the polyimide resin is left in areas where the inductor wiring line 100 is to be formed. The underlying insulation layer 33 is thus formed. In the case of an insulation film made of an inorganic material, the insulation film is formed on the substrate 70 by, for example, a dry process such as vapor deposition, sputtering, or CVD.

As illustrated in FIG. 5B, a seed layer 81 is formed on the underlying insulation layer 33. Specifically, a material (e.g., titanium/copper alloy) for the seed layer 81 is deposited onto the upper face of the underlying insulation layer 33 by sputtering, and patterned by the subtractive method to thereby form the seed layer 81.

As illustrated in FIG. 5C, the resin walls 32 are formed on the underlying insulation layer 33. The resin walls 32 are formed by use of, for example, a photosensitive permanent photoresist. A photosensitive permanent photoresist refers to a photoresist that is not removed after undergoing processing. Specifically, the substrate 70 is printed with a material for the resin walls 32, and then subjected to exposure. Developing is then performed by use of an organic solvent such as propylene glycol monomethyl ether acetate (PGMEA), and an alkaline developer such as tetramethylammonium hydroxide (TMAH). As a result, the material is removed in areas not exposed to light. The resin walls 32 are thus formed.

As illustrated in FIG. 5D, the second pad portion 112 and the spiral portion 120 are formed over the seed layer 81. Specifically, plating is grown on the seed layer 81 by electrolytic plating. The second pad portion 112 and the spiral portion 120 are thus formed between the resin walls 32.

FIGS. 5E to 5H are enlarged views of a location where the second via-wiring line is to be provided. As illustrated in FIG. 5E, a photosensitive insulation layer 310 is disposed so as to cover the upper face of the second pad portion 112, and the upper face of the spiral portion 120 (not illustrated). Specifically, a photosensitive insulation film is laminated so as to cover the upper face of the second pad portion 112 and the upper face of the spiral portion 120. The photosensitive insulation film is likewise made of a photosensitive permanent photoresist. The photosensitive insulation film to be used is preferably a negative film. The following description assumes that the photosensitive insulation film used is a negative film.

As illustrated in FIG. 5F, a photomask M is placed over the photosensitive insulation layer 310, and exposure is performed on the photosensitive insulation layer 310 by illuminating the photosensitive insulation layer 310 with, for example, ultraviolet radiation L applied from above the photomask M. At this time, the focus of an exposure system is positioned above the upper face of the photosensitive insulation layer 310 to thereby reduce the amount of light to which the photosensitive insulation layer 310 is to be exposed. As a result, a solidified portion 311 is formed in an upper part of the photosensitive insulation layer 310, and thus the photosensitive insulation layer 310 is now in a semi-solidified state. The exposure system to be used is preferably a projection exposure system with adjustable focus. Although not illustrated in FIG. 5F, a portion of the photosensitive insulation layer 310 located between the solidified portion 311 and the second pad portion 112 has also been slightly solidified due to heat generated during the exposure. The heat decreases gradually in the direction from the solidified portion 311 toward the second pad portion 112. As a result, the portion of the photosensitive insulation layer 310 that has been slightly solidified due to the heat decreases in width in the direction from the solidified portion 311 toward the second pad portion 112.

As illustrated in FIG. 5G, post exposure bake (PEB) is performed to cause the photosensitive insulation layer 310 to solidify in the portion of the photosensitive insulation layer 310 between the solidified portion 311 and the second pad portion 112 illustrated in FIG. 5F. At this time, solidification is promoted in the slightly solidified portion mentioned above. Consequently, after the PEB, the lateral face of the solidified portion 311 has a shape corresponding to the constricted shape of the second via-wiring line. As for the conditions of the PEB, for example, the PEB is performed at a temperature 10° C. to 20° C. higher, and for a duration two to three times greater, than that in the case of a normal via formation process.

As illustrated in FIG. 5H, developing is performed to remove a portion of the photosensitive insulation layer 310 other than the solidified portion 311. The via-hole 31h having a constricted shape is thus formed. The position of the constriction of the via-hole 31h can be controlled by varying the focus position during the exposure.

As illustrated in FIG. 5I, a seed layer 82 is formed by sputtering on the following locations: the inner face of the via-hole 31h; the exposed portion of the upper face of the second pad portion 112; the upper face of the inter-layer insulation layer 31; and the upper faces of the resin walls 32.

As illustrated in FIG. 5J, the second via-wiring line 222 and the second columnar wiring line 221 are formed at a location corresponding to the exposed portion of the upper face of the second pad portion 112. Specifically, a resist film 320 is formed on the seed layer 82, and a cavity is provided in the resist film 320 at a location corresponding to the second via-wiring line 222. Plating is grown on the seed layer 82 by electrolytic plating to thereby form a plating layer in the cavity. The second via-wiring line 222 and the second columnar wiring line 221 are thus formed in the cavity.

At this time, preferably, the width of a portion of the via-hole 31h where opposite inner faces of the via-hole 31h are at the closest distance from each other (i.e., the width W1 of the second end face P1e2 of the first portion P1) is greater than 0.8 times the width of a portion of the via-hole 31h where opposite inner faces of the via-hole 31h are located at the second pad portion 112 (i.e., the width W2 of the first end face P1e1 of the first portion P1). The configuration mentioned above helps to ensure that entry of a plating solution into a portion of the via-hole 31h near the second pad portion 112 is not impeded. Further, the configuration mentioned above helps to ensure that no void is generated during plating in a region that is located in the outer side portion of the first portion P1 in the widthwise direction, and that is surrounded by the first portion P1, the second pad portion 112, and the inter-layer insulation layer 31.

As illustrated in FIG. 5K, the resist film 320 is stripped off, and the resulting exposed portion of the seed layer 82 is removed. The second magnetic layer 12 is then formed on the inter-layer insulation layer 31. Further, the first magnetic layer 11 is formed on the lower face of the substrate 70. The first magnetic layer 11 and the second magnetic layer 12 are each formed by pressing of a magnetic layer onto the inter-layer insulation layer 31 or the lower face of the substrate 70. Prior to pressing of the second magnetic layer 12, a portion of the substrate 70 is ground away to adjust the thickness of the substrate 70. The substrate 70 may be removed at this time.

As illustrated in FIG. 5L, the second magnetic layer 12 is ground to allow the upper face of the second columnar wiring line 221 to be exposed.

As illustrated in FIG. 5M, the second outer terminal 52 is formed on the upper face of the second columnar wiring line 221, and the covering film 60 that covers other portions of the second magnetic layer 12 is formed. The covering film 60 is made of, for example, a solder resist. The resulting structure is then diced with a dicer into discrete pieces to thereby produce each individual inductor component 1.

### Second Embodiment

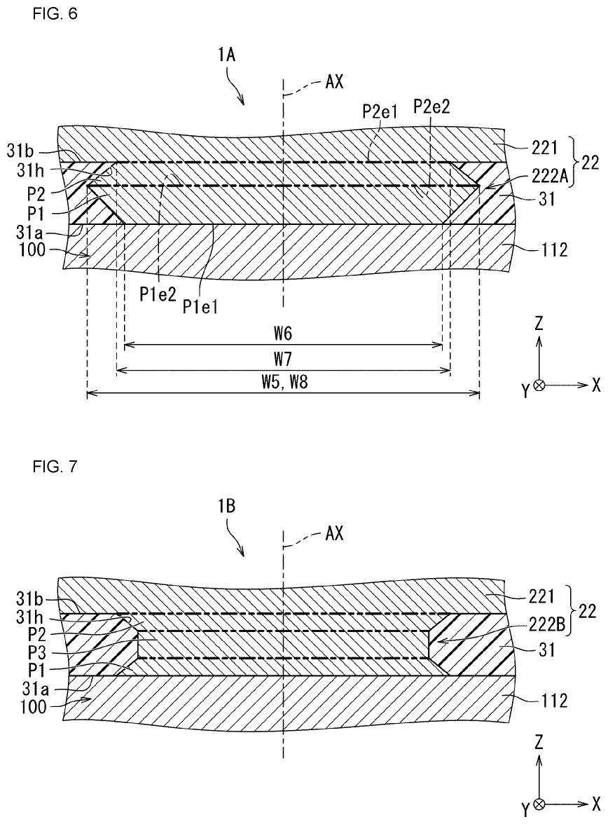

FIG. 6 is a schematic cross-sectional view of an inductor component according to a second embodiment. FIG. 6 corresponds to FIG. 3. A difference between the second embodiment and the first embodiment is the shape of the via-wiring lines. The difference is described below. Other features of the second embodiment are the same as those according to the first embodiment, and thus designated by the same reference signs as those used in the first embodiment to avoid repeated descriptions of such features.

As illustrated in FIG. 6, in an inductor component 1A according to the second embodiment, as seen in a first cross-section including the center axis AX of a second via-wiring line 222A, the second via-wiring line 222A includes a first portion P1 in contact with the inductor wiring line 100 (the second pad portion 112), and a second portion P2 in contact with the second columnar wiring line 221. The first portion P1 has a width that increases in the direction from the inductor wiring line 100 toward the second columnar wiring line 221. The second portion P2 has a width that decreases in the direction from the inductor wiring line 100 toward the second columnar wiring line 221.

Specifically, the first portion P1 has a width that increases progressively in the direction from the inductor wiring line 100 toward the second columnar wiring line 221. More specifically, as seen in the cross-section illustrated in FIG. 6, each lateral face of the first portion P1 is inclined such that its distance to the center axis AX increases in the direction from the inductor wiring line 100 toward the second columnar wiring line 221. In short, as seen in the cross-section illustrated in FIG. 6, the first portion P1 has the shape of an inverted trapezoid.

The second portion P2 has a width that decreases progressively in the direction from the inductor wiring line 100 toward the second columnar wiring line 221. More specifically, as seen in the cross-section illustrated in FIG. 6, each lateral face of the second portion P2 is inclined such that its distance to the center axis AX decreases in the direction from the inductor wiring line 100 toward the second columnar wiring line 221. In short, as seen in the cross-section illustrated in FIG. 6, the second portion P2 has the shape of a trapezoid.

According to the second embodiment, the first portion P1 and the second portion P2 are in contact with each other. In other words, the first portion P1 and the second portion P2 are contiguous to each other in the Z-direction. The first portion P1 and the second portion P2 are integral with each other.

The shape of the first portion P1 is not particularly limited as long as the first portion P1 has a width that increases in the direction from the inductor wiring line 100 toward the second columnar wiring line 221. In one example, as seen in the cross-section illustrated in FIG. 6, one lateral face of the first portion P1 may be parallel to the Z-direction. In another example, the first portion P1 may have a width that increases in a stepwise fashion in the direction from the inductor wiring line 100 toward the second columnar wiring line 221.

Likewise, the shape of the second portion P2 is not particularly limited as long as the second portion P2 has a width that decreases in the direction from the inductor wiring line 100 toward the second columnar wiring line 221. In one example, as seen in the cross-section illustrated in FIG. 6, one lateral face of the second portion P2 may be parallel to the Z-direction. In another example, the second portion P2 may have a width that decreases in a stepwise fashion in the direction from the inductor wiring line 100 toward the second columnar wiring line 221.

According to the second embodiment, the first via-wiring line is similar in configuration to the second via-wiring line 222A. That is, the first via-wiring line includes a first portion in contact with the inductor wiring line 100, and a second portion in contact with the first columnar wiring line 211. The first portion has a width that increases in the direction from the inductor wiring line 100 toward the first columnar wiring line 211, and the second portion has a width that decreases in the direction from the inductor wiring line 100 toward the first columnar wiring line 211.

According to the configuration of the inductor component 1A mentioned above, the first portion P1 of the second via-wiring line 222A has a width that increases in the direction from the inductor wiring line 100 toward the second columnar wiring line 221. This helps to reduce potential disconnection of the second via-wiring line 222A from the inter-layer insulation layer 31 in the direction from the second columnar wiring line 221 toward the inductor wiring line 100. This allows for improved strength of connection between the first portion P1 and the inductor wiring line 100. The second portion P2 of the second via-wiring line 222A has a width that decreases in the direction from the inductor wiring line 100 toward the second columnar wiring line 221. This configuration helps to reduce potential disconnection of the second via-wiring line 222A from the inter-layer insulation layer 31 in the direction from the inductor wiring line 100 toward the second columnar wiring line 221. This allows for improved strength of connection between the second portion P2 and the second columnar wiring line 221. The configuration mentioned above therefore makes it possible to improve the strength of connection between the second via-wiring line 222A, and each of the inductor wiring line 100 and the second columnar wiring line 221.

In other words, since the first portion P1 has a width that increases in the direction from the inductor wiring line 100 toward the second columnar wiring line 221, and the second portion P2 has a width that decreases in the direction from the inductor wiring line 100 toward the second columnar wiring line 221, the second via-wiring line 222A wedges into the inter-layer insulation layer 31, leading to reduced risk of disconnection of the second via-wiring line 222A from the inter-layer insulation layer 31. The configuration mentioned above makes it possible to improve the strength of connection between the second via-wiring line 222A, and each of the inductor wiring line 100 and the second columnar wiring line 221.

Preferably, as seen in a second cross-section (YZ cross-section) including the center axis AX of the second via-wiring line 222A and orthogonal to the first cross-section (XZ cross-section), the first portion P1 has a width that increases in the direction from the inductor wiring line 100 toward the second columnar wiring line 221, and the second portion P2 has a width that decreases in the direction from the inductor wiring line 100 toward the second columnar wiring line 221. This makes it possible to further improve the strength of connection between the second via-wiring line 222A, and each of the inductor wiring line 100 and the second columnar wiring line 221. Preferably, the first via-wiring line has a configuration similar to the configuration mentioned above.

Preferably, as illustrated in FIG. 6, the first portion P1 and the second portion P2 are in contact with each other. The first portion P1 includes a first end face P1e1, and a second end face P1e2. The first end face P1e1 is in contact with the inductor wiring line 100. The second end face P1e2 is in contact with the second portion P2. The second portion P2 includes a first end face P2e1, and a second end face P2e2. The first end face P2e1 is in contact with the second columnar wiring line 221. The second end face P2e2 is in contact with the first portion P1. As seen in the first cross-section, a width W5 of the second end face P1e2 of the first portion P1 is equal to a width W8 of the second end face P2e2 of the second portion P2. A width W6 of the first end face P1e1 of the first portion P1 , and a width W7 of the first end face P2e1 of the second portion P2 are less than the width W5 of the second end face P1e2 of the first portion P1 and the width W8 of the second end face P2e2 of the second portion P2. The first cross-section in this case refers to a cross-section in which the second via-wiring line 222A has the maximum width (i.e., the cross-section illustrated in FIG. 6).

The first via-wiring line may have a configuration similar to the configuration mentioned above. That is, as for the first via-wiring line as well, as seen in a first cross-section, the width of the second end face of the first portion may be equal to the width of the second end face of the second portion, and the width of the first end face of the first portion and the width of the first end face of the second portion may be less than the width of the second end face of the first portion and the width of the second end face of the second portion. The first cross-section in this case refers to a cross-section in which the first via-wiring line has the maximum width. Specifically, as seen in the Z-direction, the first cross-section refers to a cross-section passing through the opposite corners of the first via-wiring line. The configuration mentioned above provides an operational effect similar to that mentioned above with reference to the second via-wiring line 222A.

Preferably, as illustrated in FIG. 6, as seen in the first cross-section, the width W7 of the first end face P2e1 of the second portion P2 is greater than the width W6 of the first end face P1e1 of the first portion P1. The first cross-section in this case refers to a cross-section in which the second via-wiring line 222A has the maximum width (i.e., the cross-section illustrated in FIG. 6). According to the configuration previously mentioned, the second outer terminal 52 is disposed on the base body 10 at a location closer to the second columnar wiring line 221 than to the inductor wiring line 100. Accordingly, in mounting the inductor component 1, more stress tends to act at a location near the second columnar wiring line 221 than at a location near the inductor wiring line 100. At this time, since the width W7 of the first end face P2e1 of the second portion P2 of the second via-wiring line 222A is greater than the width W6 of the first end face P1e1 of the first portion P1, the area of contact of the first end face P2e1 of the second portion P2 with the second columnar wiring line 221 is greater than the area of contact of the first end face P1e1 of the first portion P1 with the inductor wiring line 100. This makes it possible to effectively reduce potential separation between the second via-wiring line 222A and the second columnar wiring line 221 caused by stress exerted in mounting the inductor component 1.

Likewise, preferably, the first portion of the first via-wiring line includes a first end face in contact with the inductor wiring line 100, and the second portion includes a first end face in contact with the first columnar wiring line 211. As seen in a first cross-section, the first end face of the second portion has a width greater than the width of the first end face of the first portion. The first cross-section in this case refers to a cross-section in which the first via-wiring line has the maximum width. Specifically, as seen in the Z-direction, the first cross-section refers to a cross-section passing through the opposite corners of the first via-wiring line. According to the configuration preciously mentioned, the first outer terminal 51 is disposed on the base body 10 at a location closer to the first columnar wiring line 211 than to the inductor wiring line 100. Accordingly, in mounting the inductor component 1, more stress tends to act at a location near the first columnar wiring line 211 than at a location near the inductor wiring line 100. At this time, since the width of the first end face of the second portion of the first via-wiring line is greater than the width of the first end face of the first portion, the area of contact of the first end face of the second portion with the first columnar wiring line 211 is greater than the area of contact of the first end face of the first portion with the inductor wiring line 100. This makes it possible to effectively reduce potential separation between the first via-wiring line and the first columnar wiring line 211 caused by stress exerted in mounting the inductor component 1.

A method for producing the inductor component 1A according to the second embodiment is described below. The inductor component 1A may be produced by a method similar to the method for producing the inductor component 1 according to the first embodiment illustrated in FIGS. 5A to 5M, except that at the step illustrated in FIG. 5F, exposure is performed with the focus of the exposure system adjusted such that the focus is located below the surface of the second pad portion 112.

### Third Embodiment

FIG. 7 is a schematic cross-sectional view of an inductor component according to a third embodiment. FIG. 7 corresponds to FIG. 3. A difference between the third embodiment and the first embodiment is the shape of the via-wiring lines. The difference is described below. Other features of the third embodiment are the same as those according to the first embodiment, and designated by the same reference signs to avoid repeated descriptions of such features.

As illustrated in FIG. 7, in an inductor component 1B according to the third embodiment, a second via-wiring line 222B includes a first portion P1, a second portion P2, and a third portion P3. The third portion P3 is located between the first portion P1 and the second portion P2. The first portion P1 is similar in configuration to the first portion P1 mentioned above with reference to the first embodiment. The second portion P2 is similar in configuration to the second portion P2 mentioned above with reference to the first embodiment.

The third portion P3 has a width that is constant in the direction from the inductor wiring line 100 toward the second columnar wiring line 221. Alternatively, the width of the third portion P3 may decrease or may increase in the direction from the inductor wiring line 100 toward the second columnar wiring line 221. According to the configuration mentioned above, the presence of the third portion P3 allows the length of the second via-wiring line 222B to be increased in the direction of the center axis AX. This allows for increased design flexibility.

A method for producing the inductor component 1B according to the third embodiment is described below. The inductor component 1B may be produced by a method similar to the method for producing the inductor component 1 according to the first embodiment illustrated in FIGS. 5A to 5M, except that at the step illustrated in FIG. 5H, after the developing, the projecting part located at the boundary between the first portion P1 and the second portion P2 may be removed by a method such as applying laser radiation to the projecting part from above.

The first via-wiring line may be similar in configuration to the second via-wiring line 222B. The inductor component 1B may include, in addition to the first portion P1, the second portion P2, and the third portion P3, a plurality of other portions.

The present disclosure is not limited to the above embodiments but may allow design variations without departing from the scope and spirit of the present disclosure. For example, features in the first to third embodiments may be used in various combinations.

According to the above embodiments, the inductor wiring line corresponds to the first inner wiring line, and each columnar wiring line corresponds to the second inner wiring line. However, the first inner wiring line and the second inner wiring line are not limited to those mentioned above. For example, the inductor component may include a first inductor wiring line and a second inductor wiring line that are arranged side by side in the Z-direction, of which the first inductor wiring line corresponds to the first inner wiring line, and the second inductor wiring line corresponds to the second inner wiring line.

The present disclosure includes aspects described below.

<1> An inductor component including a base body; a first inner wiring line and a second inner wiring line that are disposed inside the base body; and an inter-layer insulation layer disposed inside the base body and located between the first inner wiring line and the second inner wiring line. The inter-layer insulation layer includes a first major face facing the first inner wiring line, a second major face facing the second inner wiring line, and a via-hole extending through the inter-layer insulation layer between the first major face and the second major face. The inductor component further includes a via-wiring line inserted in the via-hole, the via-wiring line electrically connecting the first inner wiring line and the second inner wiring line to each other. As seen in a first cross-section including a center axis of the via-wiring line, the via-wiring line includes a first portion in contact with the first inner wiring line, and a second portion in contact with the second inner wiring line. The first portion has a width that decreases in a direction from the first inner wiring line toward the second inner wiring line, and the second portion has a width that increases in the direction from the first inner wiring line toward the second inner wiring line.

<2> The inductor component according to Item <1>,in which as seen in a second cross-section including the center axis of the via-wiring line and orthogonal to the first cross-section, the first portion has a width that decreases in the direction from the first inner wiring line toward the second inner wiring line, and the second portion has a width that increases in the direction from the first inner wiring line toward the second inner wiring line.

<3> The inductor component according to Item <1> or <2>, in which the first portion and the second portion are in contact with each other. The first portion includes a first end face in contact with the first inner wiring line, and a second end face is in contact with the second portion. Also, the second portion includes a first end face in contact with the second inner wiring line, and a second end face in contact with the first portion. In addition, in which as seen in the first cross-section, a width of the second end face of the first portion is equal to a width of the second end face of the second portion, and a width of the first end face of the first portion and a width of the first end face of the second portion are greater than the width of the second end face of the first portion and the width of the second end face of the second portion.

<4> The inductor component according to Item <3>, in which as seen in the first cross-section, the width of the second end face of the first portion is greater than 0.8 times the width of the first end face of the first portion.

<5> An inductor component including a base body; a first inner wiring line and a second inner wiring line that are disposed inside the base body; and an inter-layer insulation layer disposed inside the base body and located between the first inner wiring line and the second inner wiring line. The inter-layer insulation layer includes a first major face facing the first inner wiring line, a second major face facing the second inner wiring line, and a via-hole extending through a portion of the inter-layer insulation layer between the first major face and the second major face. The inductor component further includes a via-wiring line inserted in the via-hole. The via-wiring line electrically connects the first inner wiring line and the second inner wiring line to each other. As seen in a first cross-section including a center axis of the via-wiring line, the via-wiring line includes a first portion in contact with the first inner wiring line, and a second portion in contact with the second inner wiring line. The first portion has a width that increases in a direction from the first inner wiring line toward the second inner wiring line, and the second portion has a width that decreases in the direction from the first inner wiring line toward the second inner wiring line.

<6> The inductor component according to Item <5>, in which as seen in a second cross-section including the center axis of the via-wiring line and orthogonal to the first cross-section, the first portion has a width that increases in the direction from the first inner wiring line toward the second inner wiring line, and the second portion has a width that decreases in the direction from the first inner wiring line toward the second inner wiring line.

<7> The inductor component according to any one of Items <1> to <6>, further including an outer terminal disposed on the base body at a location closer to the second inner wiring line than to the first inner wiring line, the outer terminal being electrically connected to the second wiring line. The first portion includes a first end face in contact with the first inner wiring line. The second portion includes a first end face in contact with the second inner wiring line. Also, as seen in the first cross-section, the first end face of the second portion has a width greater than a width of the first end face of the first portion.

<8> The inductor component according to any one of Items <1> to <7>, in which the via-hole has an inner face with a mean surface roughness of less than or equal to 1 μm.

What is claimed is:

1. An inductor component comprising:
a base body;
a first inner wiring line and a second inner wiring line that are inside the base body;
an inter-layer insulation layer inside the base body and between the first inner wiring line and the second inner wiring line, the inter-layer insulation layer including
a first major face facing the first inner wiring line,
a second major face facing the second inner wiring line, and
a via-hole extending through the inter-layer insulation layer between the first major face and the second major face; and
a via-wiring line in the via-hole, the via-wiring line electrically connecting the first inner wiring line and the second inner wiring line to each other,
wherein as seen in a first cross-section including a center axis of the via-wiring line,
the via-wiring line includes
a first portion in contact with the first inner wiring line, and
a second portion in contact with the second inner wiring line,
the first portion having a width that decreases in a direction from the first inner wiring line toward the second inner wiring line,
the second portion having a width that increases in the direction from the first inner wiring line toward the second inner wiring line.

2. The inductor component according to claim 1, wherein
as seen in a second cross-section including the center axis of the via-wiring line and orthogonal to the first cross-section,
the first portion has a width that decreases in the direction from the first inner wiring line toward the second inner wiring line, and
the second portion has a width that increases in the direction from the first inner wiring line toward the second inner wiring line.

3. The inductor component according to claim 1, wherein
the first portion and the second portion are in contact with each other,
wherein the first portion includes
a first end face in contact with the first inner wiring line, and
a second end face in contact with the second portion,
wherein the second portion includes
a first end face in contact with the second inner wiring line, and
a second end face in contact with the first portion, and
wherein as seen in the first cross-section,
a width of the second end face of the first portion is equal to a width of the second end face of the second portion, and
a width of the first end face of the first portion and a width of the first end face of the second portion are greater than the width of the second end face of the first portion and the width of the second end face of the second portion.

4. The inductor component according to claim 3, wherein
as seen in the first cross-section,
the width of the second end face of the first portion is greater than 0.8 times the width of the first end face of the first portion.

5. An inductor component comprising:
a base body;
a first inner wiring line and a second inner wiring line that are inside the base body;
an inter-layer insulation layer inside the base body and between the first inner wiring line and the second inner wiring line, the inter-layer insulation layer including
a first major face facing the first inner wiring line,
a second major face facing the second inner wiring line, and
a via-hole extending through a portion of the inter-layer insulation layer between the first major face and the second major face; and
a via-wiring line in the via-hole, the via-wiring line electrically connecting the first inner wiring line and the second inner wiring line to each other,
wherein as seen in a first cross-section including a center axis of the via-wiring line,
the via-wiring line includes
a first portion in contact with the first inner wiring line, and
a second portion in contact with the second inner wiring line,
the first portion having a width that increases in a direction from the first inner wiring line toward the second inner wiring line,
the second portion having a width that decreases in the direction from the first inner wiring line toward the second inner wiring line.

6. The inductor component according to claim 5, wherein
as seen in a second cross-section including the center axis of the via-wiring line and orthogonal to the first cross-section,
the first portion has a width that increases in the direction from the first inner wiring line toward the second inner wiring line, and
the second portion has a width that decreases in the direction from the first inner wiring line toward the second inner wiring line.

7. The inductor component according to claim 1, further comprising:
an outer terminal on the base body at a location closer to the second inner wiring line than to the first inner wiring line, the outer terminal being electrically connected to the second inner wiring line,
wherein
the first portion includes a first end face in contact with the first inner wiring line,
the second portion includes a first end face in contact with the second inner wiring line, and
as seen in the first cross-section,
the first end face of the second portion has a width greater than a width of the first end face of the first portion.

8. The inductor component according to claim 1, wherein
the via-hole has an inner face with a mean surface roughness of less than or equal to 1 μm.

9. The inductor component according to claim 2, further comprising:
an outer terminal on the base body at a location closer to the second inner wiring line than to the first inner wiring line, the outer terminal being electrically connected to the second inner wiring line,
wherein
the first portion includes a first end face in contact with the first inner wiring line,
the second portion includes a first end face in contact with the second inner wiring line, and
as seen in the first cross-section,
the first end face of the second portion has a width greater than a width of the first end face of the first portion.

10. The inductor component according to claim 3, further comprising:
an outer terminal on the base body at a location closer to the second inner wiring line than to the first inner wiring line, the outer terminal being electrically connected to the second inner wiring line,
wherein
the first portion includes a first end face in contact with the first inner wiring line,
the second portion includes a first end face in contact with the second inner wiring line, and
as seen in the first cross-section,
the first end face of the second portion has a width greater than a width of the first end face of the first portion.

11. The inductor component according to claim 4, further comprising:
an outer terminal on the base body at a location closer to the second inner wiring line than to the first inner wiring line, the outer terminal being electrically connected to the second inner wiring line,
wherein
the first portion includes a first end face in contact with the first inner wiring line,
the second portion includes a first end face in contact with the second inner wiring line, and
as seen in the first cross-section,
the first end face of the second portion has a width greater than a width of the first end face of the first portion.

12. The inductor component according to claim 5, further comprising:
an outer terminal on the base body at a location closer to the second inner wiring line than to the first inner wiring line, the outer terminal being electrically connected to the second inner wiring line,
wherein
the first portion includes a first end face in contact with the first inner wiring line,
the second portion includes a first end face in contact with the second inner wiring line, and
as seen in the first cross-section,
the first end face of the second portion has a width greater than a width of the first end face of the first portion.

13. The inductor component according to claim 6, further comprising:
an outer terminal on the base body at a location closer to the second inner wiring line than to the first inner wiring line, the outer terminal being electrically connected to the second inner wiring line,
wherein
the first portion includes a first end face in contact with the first inner wiring line,
the second portion includes a first end face in contact with the second inner wiring line, and
as seen in the first cross-section,
the first end face of the second portion has a width greater than a width of the first end face of the first portion.

14. The inductor component according to claim 2, wherein
the via-hole has an inner face with a mean surface roughness of less than or equal to 1 μm.

15. The inductor component according to claim 3, wherein
the via-hole has an inner face with a mean surface roughness of less than or equal to 1 μm.

16. The inductor component according to claim 4, wherein
the via-hole has an inner face with a mean surface roughness of less than or equal to 1 μm.

17. The inductor component according to claim 5, wherein
the via-hole has an inner face with a mean surface roughness of less than or equal to 1 μm.

18. The inductor component according to claim 6, wherein
the via-hole has an inner face with a mean surface roughness of less than or equal to 1 μm.
